(19) United States
(12) Patent Application Publication
(10) Pub. No.: US 2011/0205802 A1
(43) Pub. Date: Aug. 25, 2011

(54) NONVOLATILE MEMORY DEVICE AND METHOD OF READING THE SAME

(75) Inventors: Byeong-In CHOE, Yongin-si (KR); Sung-Il Chang, Hwaseong-si (KR); Changseok Kang, Seongnam-si (KR)

(73) Assignee: Samsung Electronics Co., Ltd.

(21) Appl. No.: 13/029,947

(22) Filed: Feb. 17, 2011

(30) Foreign Application Priority Data
Feb. 22, 2010 (KR) 10-2010-0015843

(51) Int. Cl. G11C 16/04

(52) U.S. Cl. 365/185.18

(57) ABSTRACT

Provided are a nonvolatile memory device and a method of reading the same. The nonvolatile memory device includes: a memory cell; a transistor disposed between a common source line and the memory cell; and a control logic for controlling a bias voltage of the transistor to reduce the amount of current flowing into the common source line during a read operation. The method includes: applying a read voltage to the memory cell; and controlling a bias voltage of the transistor to reduce the amount of current flowing into the common source line.

### CROSS-REFERENCE TO RELATED APPLICATIONS

This U.S. non-provisional patent application claims priority under 35 U.S.C. §119 of Korean Patent Application No. 10-2010-0015843, filed on Feb. 22, 2010, the entire contents of which are hereby incorporated herein by reference.

### BACKGROUND

The present disclosure herein relates to a semiconductor memory device, and more particularly, to a nonvolatile memory device for reducing noise of a common source line and a method of reading the same.

A semiconductor memory device is generally classified into a volatile memory device and a nonvolatile memory device. The volatile memory device loses its stored data when no power is applied thereto, but the nonvolatile memory device retains its stored contents even though no power is applied thereto. The nonvolatile memory device includes various types of memory cell transistors. That is, the nonvolatile memory device includes a flash memory, a ferroelectric RAM (FRAM), a magnetic RAM (MRAM), and a phase change RAM (PRAM) according to structures of the memory cell transistors.

The flash memory device is largely classified into a NOR flash memory device and a NAND flash memory device according to a cell array structure. The NOR flash memory device has such a structure that memory cell transistors are separately connected to bit lines and word lines, respectively. Accordingly, the NOR flash memory device has an excellent random access time property. On the contrary, the NAND flash memory device has such a structure that a plurality of memory cell transistors is connected in series. This structure is called a cell string, which requires one bit line contact per cell string. Accordingly, the NAND flash memory device has an excellent integration property.

The flash memory device includes a memory cell array for storing data. The memory cell array includes a plurality of memory blocks. Each memory block includes a plurality of pages. Each page includes a plurality of memory cells. Each memory cell is classified into an ON cell and an OFF cell according to a threshold voltage distribution. The ON cell is an erased cell, and the OFF cell is a programmed cell. With the structural properties, the flash memory device may perform an erase operation by a memory block unit and a read or write operation by a page unit.

The flash memory device, that is, the NAND flash memory device includes a cell string structure. With the cell string structure, a cell string includes a string select transistor (SST) connected to a string select line (SSL), memory cells each connected to a plurality of word lines WL, and a ground select transistor (GST) connected to a ground select line (GSL). The SST is connected a bit line (BL), and the GST is connected to a common source line (CSL).

If a noise voltage occurs on the CSL, it may cause malfunction of the flash memory device. For example, upon a verify operation, such malfunction may include that insufficiently programmed memory cells can be judged to be a sufficiently programmed memory cell. Even though insufficiently programmed memory cells are judged to be a programmed memory cell upon the verify operation, they may be judged to be a memory cell which is not programmed, at a read operation.

### SUMMARY

Embodiments of the inventive concept provide nonvolatile memory devices including: a memory cell; a transistor disposed between a common source line and the memory cell; and a control logic for controlling a bias voltage of the transistor to reduce the amount of current flowing into the common source line during a read operation. The nonvolatile memory devices further includes a plurality of memory cells disposed between a bit line and the common source line and connected in series to the memory cell.

In other embodiments of the inventive concept, nonvolatile memory devices include: a plurality of memory cells connected in series; a transistor between a common source line and the plurality of memory cells; and a control logic for controlling bias voltages applied to the plurality of memory cells and the transistor, wherein the control logic controls a non-select read voltage applied to an unselected memory cell among the plurality of memory cells and a bias voltage of the transistor to reduce the amount of current flowing into the common source line during a read operation.

In still other embodiments of the inventive concept, methods of reading a nonvolatile memory device including a memory cell and a transistor between a common source line and the memory cell, the methods including: applying a read voltage to the memory cell; and controlling a bias voltage of the transistor to reduce the amount of current flowing into the common source line.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a block diagram illustrating a nonvolatile memory device according to an embodiment of the inventive concept;

FIG. 2 is a circuit diagram illustrating a structure of a memory cell array of a flash memory device;

FIG. 3 is a view illustrating an error of a threshold voltage of a memory cell;

FIG. 4 is a view illustrating the number of on cells when a program verify voltage is applied to a selected word line;

FIG. 5 is a view illustrating a threshold voltage distribution of insufficiently programmed memory cells;

FIG. 6 is a circuit diagram illustrating a cell string structure of a flash memory device according to a first embodiment of the inventive concept;

FIG. 7 is a table illustrating bias voltage requirements in a cell string structure according to the first embodiment of the inventive concept;

FIG. 8 is a view illustrating a cell distribution of current control memory cells according to a second embodiment of the inventive concept;

FIG. 9 is a table illustrating bias voltage requirements in a cell string structure according to the second embodiment of the inventive concept;

FIG. 10 is a circuit diagram illustrating a cell string structure of a flash memory device according to a third embodiment of the inventive concept;

FIG. 11 is the table illustrating bias voltage requirements in a cell string structure according to the third embodiment of the inventive concept;

FIG. 12 is a circuit diagram illustrating a cell string structure of a flash memory device according to a fourth embodiment of the inventive concept;

FIG. 13 is a table illustrating bias voltage requirements in a cell string structure according to the fourth embodiment of the inventive concept;

FIG. 14 is a block diagram illustrating a memory cell array according to an embodiment of the inventive concept;

FIG. 15 is a perspective view illustrating one of the memory blocks BLK1 to BLKi;

FIG. 16 is a cross-sectional view taken along the line I-I′ of the memory block BLKi;

FIG. 17 is a cross-sectional view illustrating the transistor structure TS of FIG. 16;

FIG. 18 is a circuit diagram illustrating an equivalent circuit of the memory block BLKi described with reference to FIGS. 15 through 17;

FIG. 19 is a block diagram illustrating a user device including a nonvolatile memory device according to an embodiment of the inventive concept;

FIG. 20 is a block diagram illustrating another user device including a nonvolatile memory device according to an embodiment of the inventive concept; and

FIG. 21 is a block diagram illustrating another user device including a nonvolatile memory device according to an embodiment of the inventive concept.

### DETAILED DESCRIPTION OF THE EMBODIMENTS

Advantages and features of the inventive concept and method of accomplishing them will be described in more detail with the accompanying drawings and embodiments below. However, the inventive concept may, however, be embodied in different forms and should not be construed as limited to the embodiments set forth herein. Hereinafter, preferred embodiments of the inventive concept will be described with reference to the accompanying drawings to fully explain the inventive concept in such a manner that it may easily be carried out by a person with ordinary skill in the art to which the inventive concept pertains.

In the drawings, the thicknesses of layers and regions are exaggerated for clarity. Like reference numerals in the drawings denote like elements, and thus their description will be omitted.

While specific terms were used, they were not used to limit the meaning or the scope of the inventive concept described in Claims, but merely used to explain the inventive concept. Accordingly, a person having ordinary skill in the art will understand from the above that various modifications and other equivalent embodiments are also possible.

As used herein, the term ‘and/or’ includes any and all combinations of one or more of the associated listed items. In addition, expressions ‘connected/combined’ mean that it can be directly connected to another component or intervening other components may also be present.

The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Hereinafter, exemplary embodiments of the inventive concept will be described in detail with reference to the accompanying drawings.

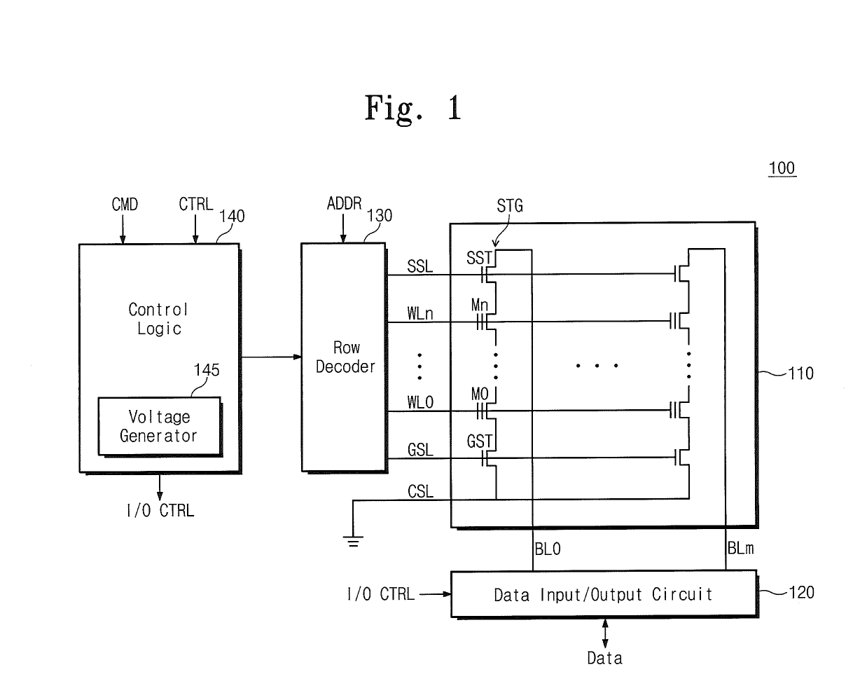

FIG. 1 is a block diagram illustrating a nonvolatile memory device according to an embodiment of the inventive concept. The nonvolatile memory device 100 will be a NAND flash memory device. However, it is apparent that the nonvolatile memory device 100 is not limited to the NAND flash memory device. For example, the nonvolatile memory device 100 may be formed of any one of nonvolatile memory devices such as a NOR flash memory device, a Phase-change RAM (PRAM), a Ferroelectric RAM (FRAM), a Magnetic RAM (MRAM), and the like.

Referring to FIG. 1, as the non-volatile memory device, the NAND flash memory device 100 (hereinafter, referred to as a flash memory device) includes a memory cell array 110, a data input/output circuit 120, a row decoder 130, and control logic 140. The control logic 140 includes a voltage generator 145.

The memory cell array 110 includes memory cells for storing data. Although not shown in FIG. 1, the memory cell array 110 may be formed of a plurality of blocks (or, memory blocks). Each of the blocks includes a plurality of pages. Each of the plurality of pages is formed of a plurality of memory cells. With structural properties of the flash memory device 100, a read or write/program operation is carried out by a page unit, and an erase operation is carried out by a block unit.

For ease of illustration, one memory block is illustrated in FIG. 1 as an example. The memory block includes a plurality of cell strings each connected to a plurality of bit lines BL0 to BLm. The cell strings are configured to have the same structure. A cell string STG includes a string select transistor SST connected to a string select line SSL, a plurality of memory cells M0 to Mn each connected to a plurality of word lines WL0 to WLn, and a ground select transistor GST connected to a ground select line GSL. The string select transistor SST is connected to a bit line BL0, and the ground select transistor GST is connected to a common source line CSL.

Each memory cell of the memory cell array 110 may store single-bit data or multi-bit data. A memory cell for storing single-bit data is called a Single Level Cell (SLC), and a memory cell for storing multi-bit data of two or more bits is called a Multi Level Cell (MLC). The SLC may have any one of an erase state and one program state according to its threshold voltage. The MLC may have any one of an erase state and a plurality of program states according to its threshold voltage.

The data input/output circuit 120 is connected to the memory cell array 110 through the bit lines BL0 to BLm. The data input/output circuit 120 outputs and receives data through a data input/output buffer (not shown). The data input/output circuit 120 reads data stored in selected memory cells among a plurality of memory cells through the bit lines BL0 to BLm. The read data are outputted to the external of the flash memory device 100 through the data input/output buffer.

Moreover, the data input/output circuit 120 temporarily stores data to be programmed selected memory cells among the plurality of memory cells. The data stored in the data input/output circuit 120 are programmed into the selected memory cells during a program operation. The above-described operation of the data input/output circuit 120 may be performed in response to a control signal I/O CTRL from the control logic 140.

The row decoder 130 is connected to the memory cell array 110 through the plurality of word lines WL0 to WLn. The row decoder 130 receives an address ADDR and selects a block or a page of the memory cell array 110. Herein, an address for selecting a block is called a block address, and an address for selecting a page is called a page address. The block address and the page address may constitute a row address of the memory cell array 110.

The control logic 140 controls a general operation of the flash memory device 100 in response to a command CMD and a control signal CTRL from an external source (for example, a host, a memory controller, a memory interface, and so forth). For example, the control logic 140 controls read, write (or program), and erase operations of the flash memory device 100. For these operations, the control logic 140 controls the voltage generator 145 to generate a bias voltage. The voltage generator 145 in the control logic 140 generates a bias voltage that will be provided to the bit lines BL0 to BLm or the word line WL0 to WLn during read, write, and erase operations. For example, during a read operation, the voltage generator 145 generates a select read voltage VRD to be provided to a selected word line and a non-select read voltage VREAD to be provided to an unselected word line.

According to an embodiment of the inventive concept, the control logic 140 controls a bias voltage to be provided to an unselected word line. As another example, in the event that a current control memory cell is included in each cell string STG, the control logic 140 controls a bias voltage to be provided to a word line of a current control memory cell. As a result, the amount of on-cell current flowing in the common source line CSL through a cell string is adjusted.

During a read operation or a program verify operation, the control logic 140 reduces the amount of on-cell current i_{S} flowing in the common source line CSL by controlling a bias voltage to be provided to a word line of a cell string. On-cell current i_{SC} that flows in the common source line CSL when the bias voltage is controlled is less in amount than on-cell current i_{S} that flows in the common source line CSL when the bias voltage is not controlled. Therefore, the control logic 140 may reduce a noise voltage of the common source line CSL, which occurs when current flows in the common source line CSL. This operation will be described in more detail with reference to FIG. 6.

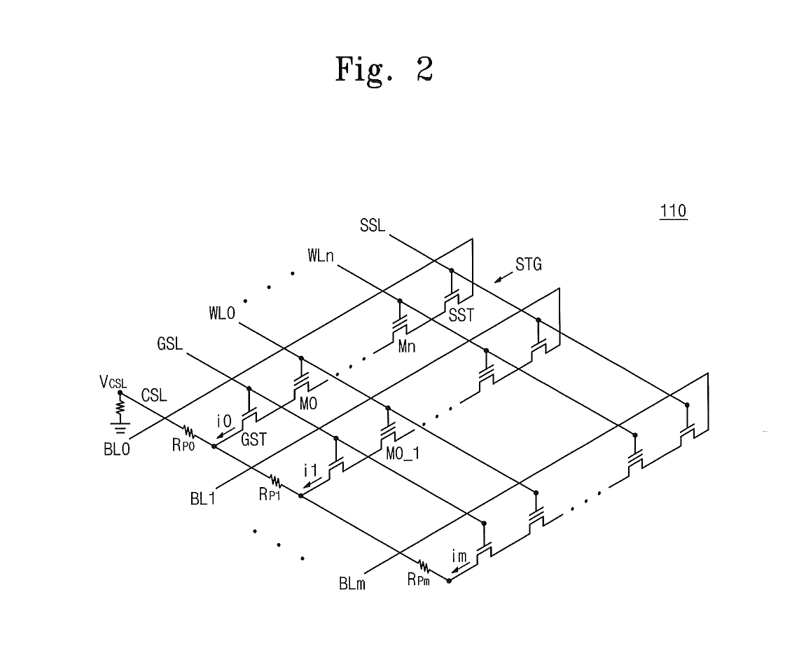

FIG. 2 is a circuit diagram illustrating a structure of a memory cell array of a flash memory device.

Referring to FIG. 2, one memory block included in the memory cell array 110 is illustrated as an example. The memory cell array 110 includes a plurality of memory cells. The memory block includes a plurality of cell strings STG each connected to a plurality of bit lines BL0 to BLm.

Each cell string STG includes a plurality of memory cells M0 to Mn connected in series between a corresponding bit line and a common source line CSL. Each cell string STG includes a string select transistor SST connected to a string select line SSL, a plurality of memory cells each connected to a plurality of word lines WL0 to WLn, and a ground select transistor GST connected to a ground select line GSL.

In each cell string, the string select transistor SST is connected to a corresponding bit line, and the ground select transistor GST is connected to the common source line CSL. In FIG. 2, resistors R_{P0} to R_{Pm} represent resistance components in the common source line CSL. For example, the resistors R_{P0} to R_{Pm} may represent a parasite resistance or a parasite capacitance (hereinafter, referred to as a parasite resistance) of the common source line CSL.

During a program verify operation or a read operation, the amount of current flowing via a cell string STG may vary according to the number of on cells in the cell string STG. A common source line voltage V_{CSL} may vary according to the amount of current flowing via the cell string STG. A variation of the common source line voltage V_{CSL} according to the number of on cells may be described under the following independent assumptions, respectively. That is, a variation of the common source line voltage V_{CSL} according to the number of on cells may be described under the first assumption that a memory cell M0 connected to a selected word line WL0 is in an erase state and a memory cell M0_1 connected to the selected word line WL0 is in a program state. A variation of the common source line voltage V_{CSL} according to the number of on cells may be described under the second assumption that when memory cells M0 and M0_1 connected to the selected word line WL0 are an on cell, currents i0 and i1 flow through cell strings STG, respectively.

With the above-described assumptions, the common source line voltage V_{CSL} may vary according to the number of on cells. For example, if the memory cell M0 connected to the selected word line WL0 is an on cell and the memory cell M0_1 connected to the selected word line WL0 is an off cell, the common source line voltage V_{CSL} is about (i0×R_{P0}). On the other hand, if the memory cells M0 and M0_1 connected to the selected word line WL0 are on cells, the common source line voltage (V_{CSL}) is about (i0×R_{P0})+(i1×R_{P1}). This means that the common source line voltage V_{CSL} may vary according to the number of on cells during a read or program verify operation.

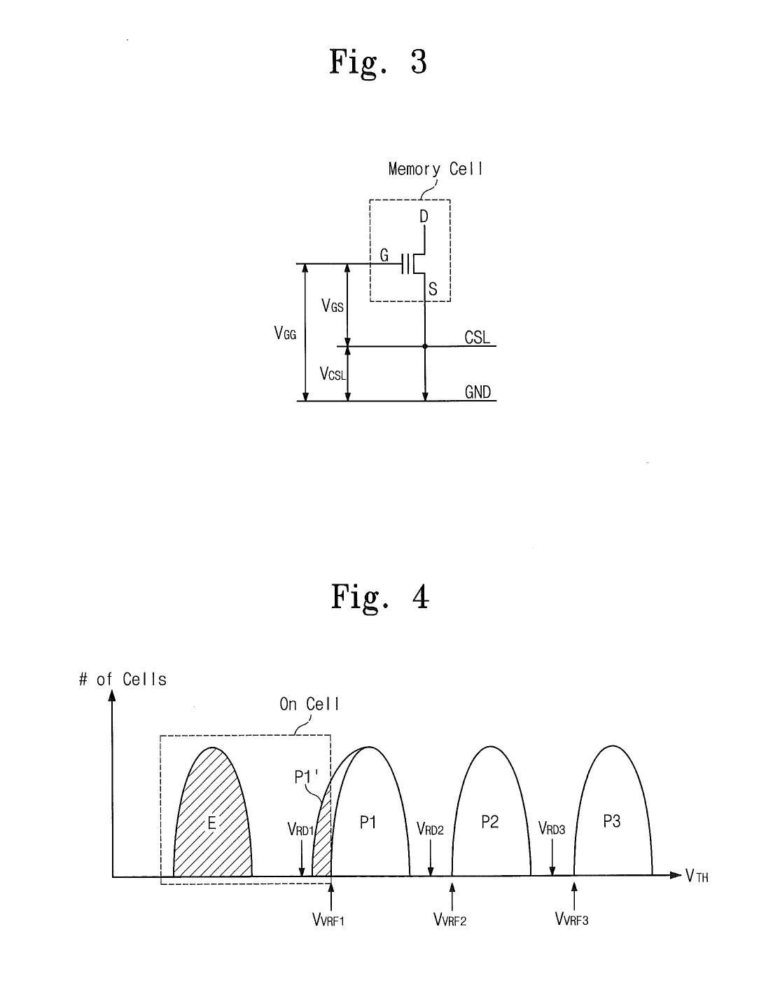

FIG. 3 is a view illustrating an error of a threshold voltage of a memory cell.

Referring to FIG. 3, one memory cell included in the memory cell array 110 of FIG. 1 is illustrated as one example. When current flows in a common source line CSL, a voltage may occur on the common source line CSL due to a parasite resistance. This voltage change of the common source line CSL becomes a noise voltage thereof, that is, a common source line voltage V_{CSL}.

In addition, a control gate G of the memory cell is controlled by a voltage provided from a voltage generator 145 of FIG. 1. The voltage generator 145 generates a voltage V_{GG} on the basis of ground GND. However, a channel formed during a program verify operation or a read operation of the memory cell is controlled by a voltage difference V_{GS} between the control gate G and the source S of the memory cell. Accordingly, during a program verify or read operation, a voltage difference V_{CR}, may be generated between the voltage V_{GG}, which is actually supplied to the control gate G of the memory cell, and the voltage V_{GS} which affects channel formation of the memory cell.

The common source line voltage V_{CSL} may cause sensing errors of a data input/output circuit 120 of FIG. 1 during a program verify operation or a read operation. The common source line voltage V_{CSL} depends on an ON or OFF state determined according to data of memory cells. Therefore, the common source line voltage V_{CSL} is not constant, has frequent changes, and is not removed easily.

FIG. 4 is a view illustrating the number of on cells when a program verify voltage is applied to a selected word line.

Referring to FIG. 4, a threshold voltage distribution of an MLC for storing data of two or more bits is illustrated. A memory cell is programmed into one of an erase state E and a plurality of program states P1, P2, and P3 according to a threshold voltage. During a read operation, the first to third select read voltages V_{RD1}, V_{RD2}, and V_{RD3} are provided sequentially to a selected word line. The first select read voltage V_{RD1} corresponds to a voltage between the erase state E and the first program state P1. The second select read voltage V_{RD2} corresponds to a voltage between the first program state P1 and the second program state P2. The third select read voltage V_{RD3} corresponds to a voltage between the second program state P2 and the third program state P3.

Moreover, during a program verify operation, the first to third program verify voltages V_{VRF1}, V_{VRF2}, and V_{VRF3} are provided to the selected word line, respectively. The first program verify voltage V_{VRF1} corresponds to a verify voltage for programming a memory cell with the first program state P1. The second program verify voltage V_{VRF2} corresponds to a verify voltage for programming a memory cell with the second program state P2. The third program verify voltage V_{VRF3} corresponds to a verify voltage for programming a memory cell with the third program state P1.

In FIG. 4, a dotted box indicates memory cells (included in a slashed portion) identified as on cells among a plurality of memory cells when the first program verify voltage V_{VRF1} is applied to a selected word line. That is, memory cells in an erase state E and memory cells in a slashed portion P1′ may be judged to be an ON cell. Herein, the memory cells in the slashed portion P1′ are memory cells, of which threshold voltages don't exceed the first program verify voltage V_{VRF1}, among memory cells to be programmed into the first program state P1. In FIG. 4, there is illustrated an ON cell distribution (for example, a slashed portion P1′) upon a program verify operation for checking whether selected memory cells are programmed into the first program state P1. Like the program state P1, ON cell distributions may be formed with respect to the second and third program states P2 and P3.

As described with reference to FIG. 2, the common source line CSL is typically connected to a ground terminal through a metal line. Since the metal line has a resistance component, the common source line voltage V_{CSL} may vary when current flows into the common source line CSL. Here, a variation of the common source line voltage V_{CSL} is proportional to the amount of cell current caused by ON cells. For example, if the amount of current flowing into the common source line CSL increases due to increase in the number of ON cells connected to a selected word line, the common source line voltage V_{CSL} may increase. The variation of the common source line voltage V_{CSL} cause a noise voltage on the common source line CSL.

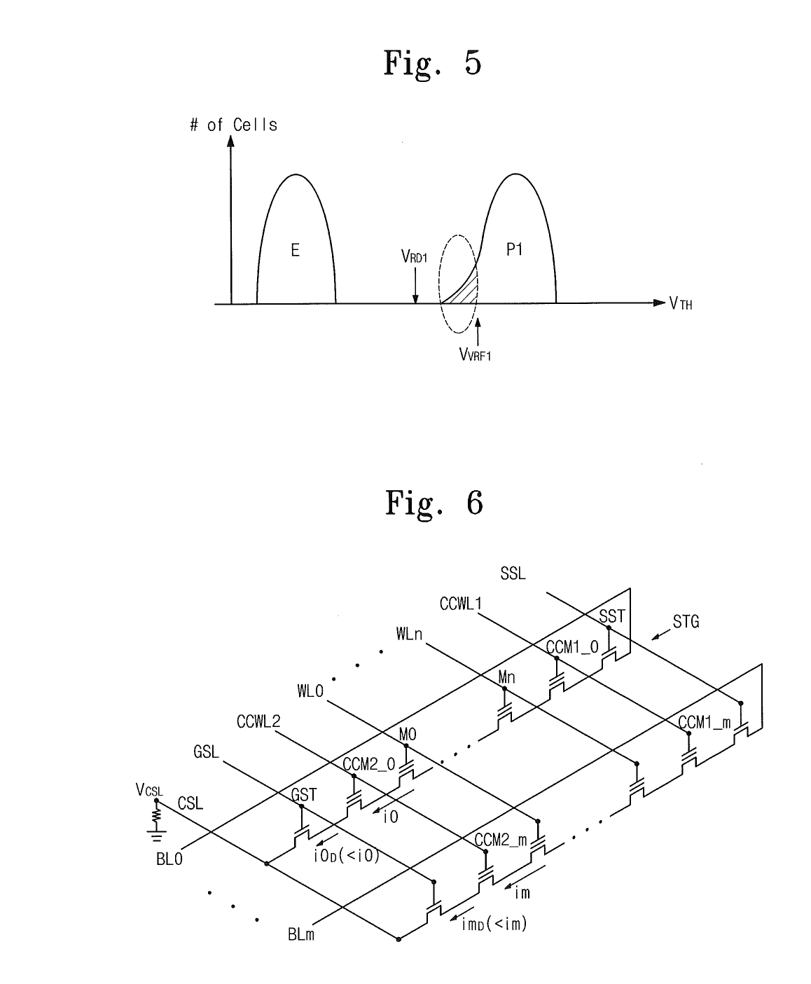

FIG. 5 is a view illustrating a threshold voltage distribution of insufficiently programmed memory cells.

As mentioned above, during a program verify operation, the amount of current flowing into a common source line CSL increases as the number of on cells increases. When the amount of current flowing into the common source line CSL increases, a common source line voltage V_{CSL} increases because of influence such as a parasite resistance. When the common source line voltage V_{CSL} increases, there is reduced the amount of current detected/sensed by the data input/output circuit 120 of FIG. 1.

Decrease in the amount of current sensed by the data input/output circuit 120 of FIG. 1 makes threshold voltages of insufficiently programmed memory cells reach the first program verity voltage V_{VRF1} of the first program state P1. This means that a program operation is completed. That is, even if memory cells are not sufficiently programmed, they may be verified as being completed, thus finishing the program operation. In this case, a threshold voltage distribution of memory cells expands/widens due to memory cells distributed in a slashed portion illustrated by a dotted circle of FIG. 5. After the program operation is finished, memory cells that do not exceed the program verify voltage V_{VRF1} may be read as memory cells that are not programmed to the first program state P1.

Although only the first program state P1 is shown in FIG. 5, the above-described malfunctions may be generated upon programming of the second and third program states P2 and P3.

FIG. 6 is a circuit diagram illustrating a cell string structure of a flash memory device according to a first embodiment of the inventive concept.

Referring to FIG. 6, one memory block according to the first embodiment of the inventive concept is illustrated as an example. A block includes a plurality of cell strings STG connected to a plurality of bit lines BL0 to BLm, respectively.

A cell string STG includes a string select transistor SST connected to a string select line SSL, a plurality of memory cells M0 to Mn each connected to a plurality of word lines WL0 to WLn, a ground select transistor GST connected to a ground select line GSL, and the first and second current control memory cells CCM1 and CCM2 for controlling current flowing into a common source line CSL through a corresponding cell string STG.

The first current control memory cell CCM1 is connected between the string select transistor SST and the memory cell Mn, and the second current control memory cell CCM2 is connected between the ground select transistor GST and the memory cell M0. The first current control memory cell CCM1 and the second current control memory cell CCM2 have the same structure as the memory cells M0 to Mn. However, the current control memory cells CCM1 and CCM1 according to the first embodiment of the inventive concept are not programmed unlike the memory cells M0 to Mn. Moreover, the current control memory cells CCM1 and CCM2 are not read unlike the memory cells M0 to Mn. That is, the current control memory cells CCM1 and CCM2 are not used as a storage element for storing data.

The second current control memory cell CCM2 reduces ON-cell current i0 that flows into the common source line CSL according to a bias voltage of the second current control word line CCWL2. The second current control memory cell CCM2 may be used as a transistor. Control logic 140 of FIG. 1 controls the bias voltage in order to allow the second current control memory cell CCM2 to operate in a triode state. Accordingly, current flowing through the second current control memory cell CCM2 is controlled according to the bias voltage applied to the second current control memory cell CCM2.

For example, when a bias voltage that is not sufficient to turn on the second current control memory cell CCM2 is applied to the second current control word line CCWL2, ON-cell current i0 flowing into a drain side of the second current control memory cell CCM2 is reduced, so that reduced ON-cell current flows toward a source side thereof. That is, the ON-cell current i0 flowing in a cell string STG is reduced through the second current control memory cell CCM2. The reduced ON-cell current i0_{D} flows toward the common source line CSL.

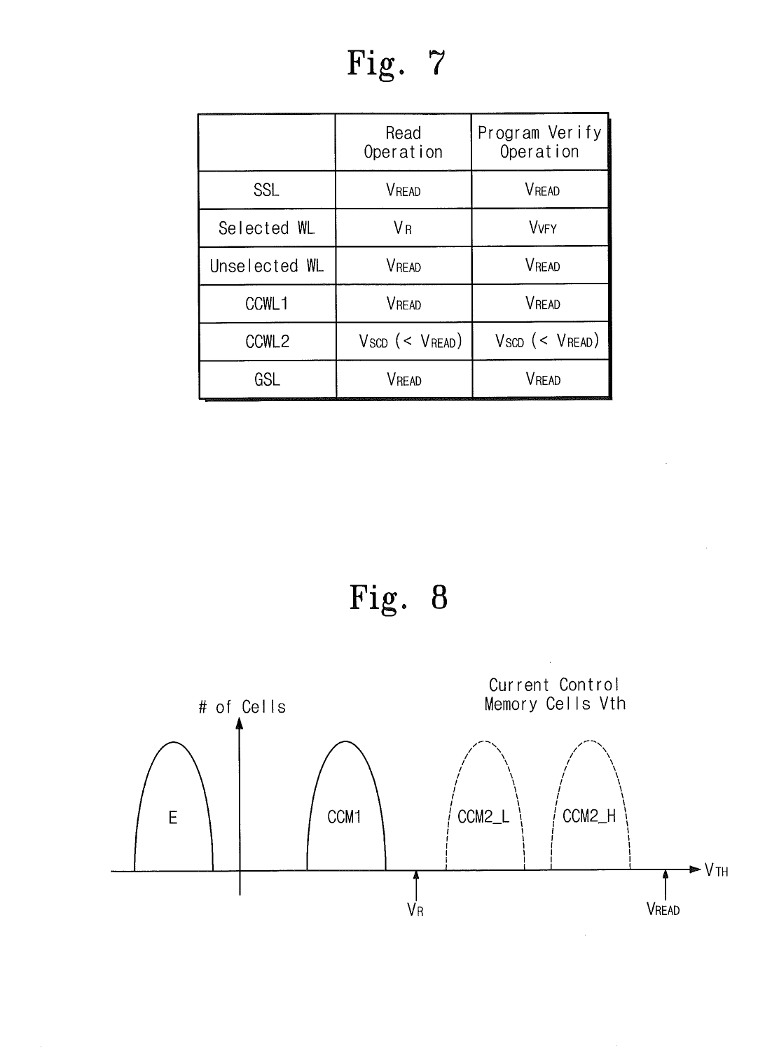

ON-cell current i0 to im flowing through a plurality of cell strings STG may be reduced according to the bias voltage applied to the second current control word line CCWL2. The reduced ON-cell current i0_{D} to imp flows into the common source line CSL. Accordingly, a common source line voltage V_{CSL}, which increases in proportion to the amount of current flowing into the common source line CSL, is reduced. Bias voltages each applied to the select lines SSL and GSL, the word lines WL0 to WLn, and the current control word lines CCWL1 and CCWL2 according to the first embodiment of the inventive concept will be described in more detail with reference to FIG. 7.

FIG. 7 is a table illustrating bias voltage conditions in a cell string structure according to the first embodiment of the inventive concept.

In FIG. 7, there are shown bias voltages which are applied to the select lines SSL and GSL, the word lines WL0 to WLn, and the current control word lines CCWL1 and CCWL2 of a cell string STG during a read operation and a program verify operation.

The bias voltage condition for a read operation is as follows. A non-select read voltage V_{READ} or a power voltage V_{CC} for sufficiently turning on select transistors SST and GST is applied to the string and ground select lines SSL and GSL, respectively. A select read voltage V_{R} is applied to a selected word lines WL so as to judge a state of a selected memory cell (for example, an erase state and a program state). A non-select read voltage V_{READ} is applied to unselected word lines to sufficiently turn on unselected memory cells. The non-select read voltage V_{READ} is higher in level than the select read voltage V_{R}.

The non-select read voltage V_{READ} is applied to the first current control word line CCWL1 to sufficiently turn on the first current control memory cell CCM1. A string current reducing voltage V_{SCD} is applied to the second current control word line CCWL2 to insufficiently turn on the second current control memory cell CCM2. Here, the string current reducing voltage V_{SCD} is higher in level than a ground voltage and is lower in level than the non-select read voltage V_{READ}. That is, the string current reducing voltage V_{SCD} is used to reduce ON-cell current that flows in a common source line CSL through a cell string STG.

Moreover, the string current reducing voltage V_{SCD} is controlled so as not to affect reading of states (for example, an erase state and a program state) of selected memory cells. For example, the string current reducing voltage V_{SCD} is controlled so as to allow pre-charged charge of selected bit lines to be discharged according to states of selected memory cells. Simultaneously, the string current reducing voltage V_{SCD} is controlled so as to allow ON-cell current flowing in the common source line CSL through a cell string STG to be reduced. That is, the string current reducing voltage V_{SCD} is set up so as not to affect reading of states (for example, an erase state and a program state) of selected memory cells and so as to reduce ON-cell current flowing in the common source line CSL.

A program operation includes an operation for programming data in selected memory cells and a program verify operation for verifying program states. The program verify operation may be the same as the read operation for reading data of selected memory cells except that read data is not output to an external source.

A bias condition for a program verify operation is as follows. The non-select read voltage V_{READ} or a power voltage V_{cc} is applied to the string select line SSL and the ground select line GSL to sufficiently turn on a selected, transistor, respectively. A program verify voltage V_{VFY} is applied to a selected word line to judge program states of selected memory cells. The non-select read voltage V_{READ} is applied to unselected word lines to sufficiently turn on unselected memory cells, respectively. The non-select read voltage V_{READ} is higher in level than a program verify voltage V_{VFY}.

The non-select read voltage V_{READ} is applied to the first current control word line CCWL1 so as to sufficiently turn on the first current control memory cell CCM1. The string current reducing voltage V_{SCD} is applied to the second current control word line CCWL2 so as to insufficiently turn on the second current control memory cell CCM2. Here, the string current reducing voltage V_{SCD} is higher in level than a ground voltage and is lower in level than the non-select read voltage V_{READ}. That is, the string current reducing voltage V_{SCD} is used to reduce ON-cell current flowing in the common source line CSL through a cell string STG.

Furthermore, the string current reducing voltage V_{SCD} is controlled so as not to affect reading of program states of selected memory cells. For example, the string current reducing voltage V_{SCD} is controlled so as to allow pre-charged charge on selected bit lines to be discharged according to states of selected memory cells. Simultaneously, the string current reducing voltage V_{SCD} is controlled so as to allow ON-cell current flowing in the common source line CSL through a cell string STG to be reduced. That is, the string current reducing voltage V_{SCD} is set up so as to reduce ON-cell current flowing in the common source line CSL and so as not to affect reading of program states of selected memory cells.

FIG. 8 is a view illustrating a cell distribution of current control memory cells according to a second embodiment of the inventive concept.

Referring to FIGS. 6 and 8, a threshold voltage distribution of the first and second current control memory cells CCM1_0 to CCM1_m and CCM2_0 to CCM2_m is illustrated. According to the second embodiment of the inventive concept, the first and second current control memory cells CCM1_0 to CCM1_m and CCM2_0 to CCM2_m may be programmed. Programming of the first and second current control memory cells CCM1_0 to CCM1_m and CCM2_0 to CCM2_m may be performed before a read operation or a program operation of a selected memory cell is performed. The first and second current control memory cells CCM1_0 to CCM1_m and CCM2_0 to CCM2_m are programmed such that turn-on states are controlled according to a threshold voltage. That is, turn-on states of the first and second current control memory cells CCM1_0 to CCM1_m and CCM2_0 to CCM2_m may vary according to how much their channels are formed.

The first current control memory cells CCM1_0 to CCM1_m are programmed such that they are sufficiently turned on when a non-select read voltage V_{READ} is applied to the cells CCM1_0 to CCM1_m. For example, the first current control memory cells CCM1_0 to CCM1_m are programmed to have threshold voltages lower in level than the select read voltage V_{R} or the non-select read voltage V_{READ}. The second current control memory cells CCM2_0 to CCM2_m are programmed such that they are sufficiently turned on when the non-select read voltage V_{READ} is applied. For example, the first current control memory cells CCM2_0 to CCM2_m are programmed to have threshold voltages which are higher in level than the select read voltage V_{R} and lower than the non-select read voltage V_{READ}.

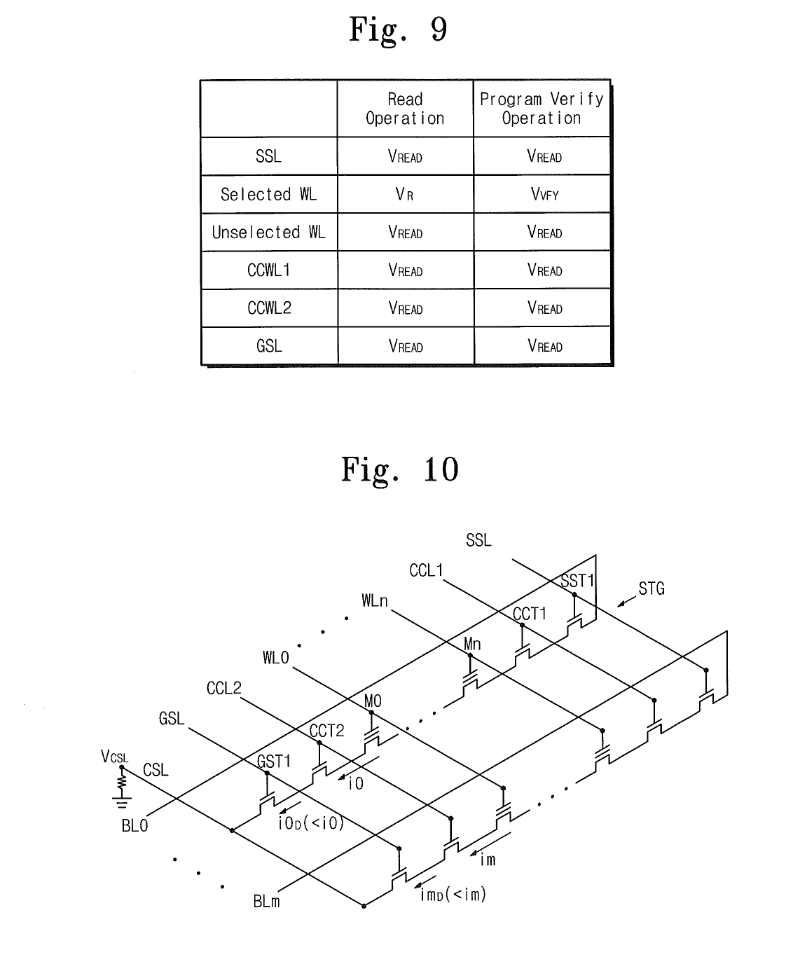

There are turned on the second current control memory cells CCM2_0 to CCM2_m of which threshold voltages are programmed to be lower in level than the non-select read voltage V_{READ}, is turned on. The turn-on states of the second current control memory cells CCM2_0 to CCM2_m may vary according to sizes of channels formed when the non-select read voltage V_{READ} is applied thereto. For example, even if the same non-select read voltage V_{READ} is applied, a channel size of the second current control memory cell CCM2_L of which a threshold voltage is programmed to be low, may be formed to be smaller than a channel size of the second current control memory cell CCM2_H of which a threshold voltage is programmed to be high. Accordingly, cell current i0 flowing into a drain side of the second current control memory cell CCM2 is controlled according to its threshold voltage, and the controlled cell current flows toward a source side thereof. A bias voltage applied to the select lines SSL and GSL, the word lines WL0 to WLn, and the current control word lines CCWL1 and CCWL2 according to the second embodiment of the inventive concept will be described in more detail with reference to FIG. 9.

FIG. 9 is a table illustrating a bias voltage condition of a cell string structure according to the second embodiment of the inventive concept.

Referring to FIGS. 6 and 9, there are shown conditions of bias voltage which are applied to the select lines SSL and GSL, the word lines WL0 to WLn, and the current control word lines CCWL1 and CCWL2 of a cell string during a read operation and a program verify operation.

The bias voltage condition for a read operation is as follows. The condition of bias voltages applied to the sting select line SSL, the ground select line GSL, the selected word line, the unselected word lines, and the first current control word line CCWL1 is identical to that shown in FIG. 7. According to the second embodiment of the inventive concept, since the second current control memory cell CCM2 is programmed such that ON-cell current is reduced, a non-select read voltage V_{READ} is applied to the second current control word line CCWL2.

The bias voltage condition for a program operation is as follows. The condition of bias voltages applied to the sting select line SSL, the ground select line GSL, the selected word line, the unselected word lines, and the first current control word line CCWL1 is identical to that shown in FIG. 7. According to the second embodiment of the inventive concept, since the second current control memory cell CCM2 is programmed such that ON-cell current is reduced, the non-select read voltage V_{READ} is applied to the second current control word line CCWL2.

FIG. 10 is a circuit diagram illustrating a cell string structure of a flash memory device according to a third embodiment of the inventive concept.

Referring to FIG. 10, one memory block according to the third embodiment of the inventive concept is illustrated as an example. A block includes a plurality of cell strings STG connected to a plurality of bit lines BL0 to BLm, respectively.

A cell string STG includes a string select transistor SST connected to a string select line SSL, a plurality of memory cells M0 to Mn each connected to a plurality of word lines WL0 to WLn, a ground select transistor GST connected to a ground select line GSL, and the first and second current control transistors CCT1 and CCT2 for controlling current that flows in a common source line CSL through a corresponding cell string STG.

The first current control transistor CCT1 is connected between the string select transistor SST and the memory cell Mn, and the second current control transistor CCT2 is connected between the ground select transistor GST and the memory cell M0. The first current control memory cell CCT1 and the second current control transistor CCT2 have the same structure as the select transistors SST and GST.

The second current control transistor CCT2 reduces ON-cell current i0 flowing into the common source line CSL according to a bias voltage of the second current control line CCL2. Control logic 140 of FIG. 1 controls a bias voltage such that the second current control transistor CCT2 operates in a triode state. Accordingly, current flowing through the second current control transistor CCT2 is controlled according to a bias voltage applied to the second current control transistor CCT2.

For example, when a bias voltage that does not sufficiently turn on the second current transistor CCT2 is applied to the second current control line CCL2, ON-cell current i0 flowing into a drain side of the second current control transistor CCT2 is reduced, and the reduced cell current flows toward a source side thereof. That is, the ON-cell current i0 flowing via a cell string STG is reduced through the second current control transistor CCT2. The reduced ON-cell current i0_{D} flows toward the common source line CSL.

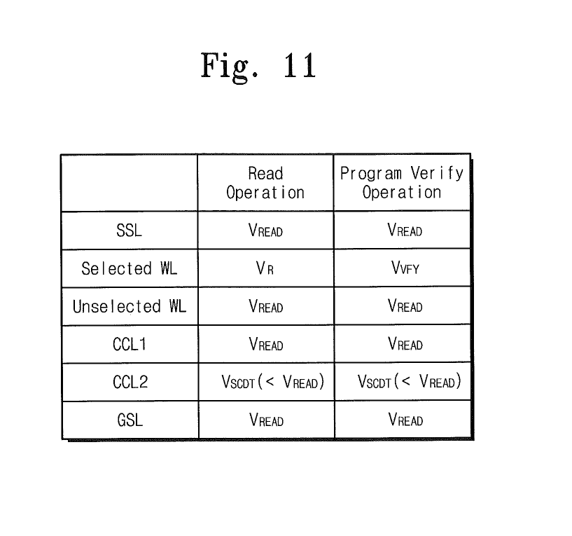

ON-cell current i0 to im flowing through a plurality of cell strings STG may be reduced according to a bias voltage applied to the second current control line CCL2. The reduced ON-cell current i0_{D} to im_{D} may flow into the common source line CSL. Accordingly, there is reduced the common source line voltage V_{CSL} which increases in proportion to current flowing through the common source line CSL. Bias voltages applied to the select lines SSL and GSL, the word lines WL0 to WLn, and the current control lines CCL1 and CCL2 according to the third embodiment of the inventive concept will be described in more detail with reference to FIG. 11.

FIG. 11 is the table illustrating bias voltage requirements in a cell string structure according to the third embodiment of the inventive concept.

Referring to FIGS. 10 and 11, there is shown conditions of bias voltages which are applied to the select lines SSL and GSL, the word lines WL0 to WLn, and the current control lines CCL1 and CCL2 of a cell string STG during a read operation and a program verify operation.

The bias voltage condition for a read operation is as follows. A non-select read voltage V_{READ} or a power voltage V_{CC} for sufficiently turning on string and ground select transistors is applied to the string select line SSL and the ground select line GSL. A select read voltage V_{R} is applied to the selected word line so as to determine states of selected memory cells (for example, an erase state and a program state). The non-select read voltage V_{READ} is applied to unselected word lines to sufficiently turn on unselected memory cells. The non-select read voltage V_{READ} is higher in level than the select read voltage V_{RD}.

The non-select read voltage V_{READ} is applied to the first current control line CCL1 to sufficiently turn on the first current control memory cell CCT1. A string current reducing voltage V_{SCDT} is applied to the second current control line CCL2 such that the second current control transistor CCT2 is not sufficiently turned on. Here, the string current reducing voltage V_{SCDT} is higher in level than a ground voltage and is lower in level than the non-select read voltage V_{READ}. That is, the string current reducing voltage V_{SCDT} is used to reduce ON-cell current that flows into the common source line CSL through a cell string STG.

Moreover, the string current reducing voltage V_{SCDT} is controlled so as not to affect reading of states (for example, an erase state and a program state) of selected memory cells. For example, the string current reducing voltage V_{SCDT} is controlled so as to allow pre-charged charge on selected bit lines to be discharged according to states of selected memory cells. Simultaneously, the string current reducing voltage V_{SCDT} is controlled such that ON-cell current flowing into the common source line CSL through a cell string STG is reduced. That is, the string current reducing voltage V_{SCDT} is controlled so as not to affect reading of states (for example, an erase state and a program state) of selected memory cells and so as to reduce ON-cell current flowing into the common source line CSL.

A bias voltage condition for a program verify operation is as follows. A non-select read voltage V_{READ} or a power voltage V_{CC} is applied to the string select line SSL and the ground select line GSL so as to sufficiently turn on select transistors. A program verify voltage V_{VFY} is applied to a selected word line to determine program states of selected memory cells. A non-select read voltage V_{READ} is applied to unselected word lines so as to sufficiently turn on unselected memory cells. The non-select read voltage V_{READ} is higher in level than a program verify voltage V_{VFY}.

The non-select read voltage V_{READ} is applied to the first current control line CCL1 so as to sufficiently turn on the first current control transistor CCT1. A string current reducing voltage V_{SCDT} is applied to the second current control line CCL2 so as not to sufficiently turn on the second current control transistor CCT2. Here, the string current reducing voltage V_{SCDT} is higher in level than a ground voltage and is lower in level than the non-select read voltage V_{READ}. That is, the string current reducing voltage V_{SCDT} is used to reduce ON-cell current flowing into the common source line CSL through a cell string STG.

Furthermore, the string current reducing voltage V_{SCDT} is controlled so as not to affect reading of program states of selected memory cells. For example, the string current reducing voltage V_{SCDT} is controlled so as to allow pre-charged charge on selected bit lines to be discharged according to states of selected memory cells. Simultaneously, the string current reducing voltage V_{SCD} is controlled such that ON-cell current flowing into the common source line CSL through a cell string STG is reduced. That is, the string current reducing voltage V_{SCDT} is controlled so as not to affect reading of program states of selected memory cells and so as to reduce ON-cell current flowing into the common source line CSL.

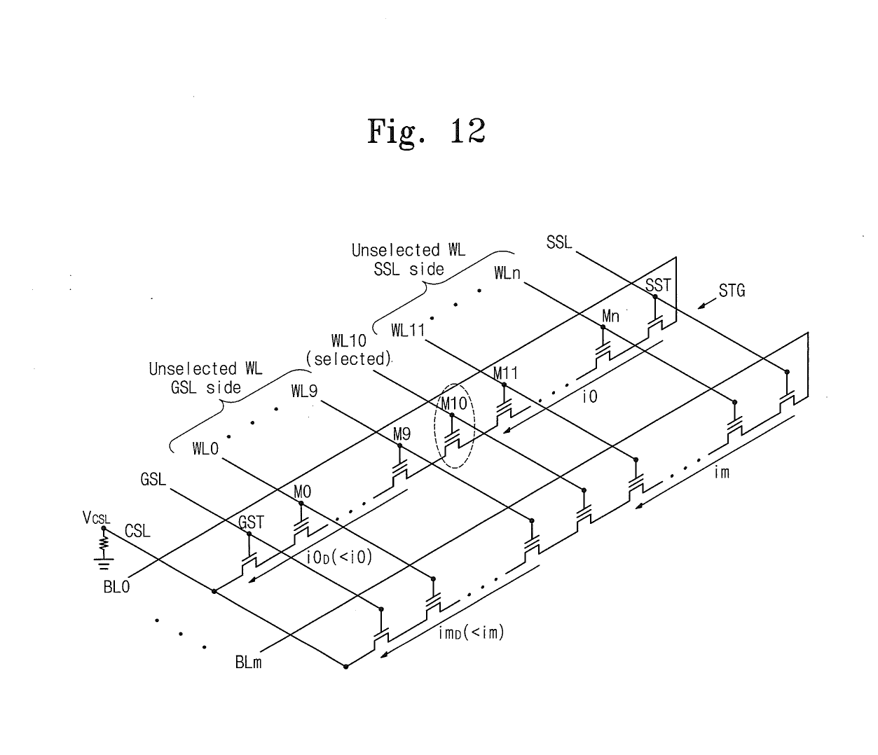

FIG. 12 is a circuit diagram illustrating a cell string structure of a flash memory device according to a fourth embodiment of the inventive concept.

Referring to FIG. 12, one memory block according to the fourth embodiment of the inventive concept is illustrated as an example. A block includes a plurality of cell strings STG each connected to a plurality of bit lines BL0 to BLm. Each cell string STG includes a string select transistor SST connected to a string select line SSL, a plurality of memory cells M0 to Mn each connected to a plurality of word lines WL0 to WLn, and a ground select transistor GST connected to a ground select line GSL.

According to the fourth embodiment of the inventive concept, unselected memory cells and a ground select transistor GST, which are connected between a selected memory cell and a common source line CSL, may be used to reduce ON-cell current i0 flowing into the common source line CSL according to their bias voltages. With the fourth embodiment of the inventive concept, the unselected memory cells (for example, M0 to M9) connected between the selected memory cell (for example, M10) and the common source line CSL are used as a transistor. Control logic 140 of FIG. 1 controls a bias voltage condition such that the unselected memory cells and the ground select transistor GST, which are connected between the selected memory cell and the common source line CSL, operate in a triode state. Accordingly, current flowing through the unselected memory cells and the ground select transistor, which are connected between the selected memory and the common source line CSL, is controlled according to a bias voltage condition.

For example, when the unselected word lines WL0 to WL9 are supplied with a bias voltage by which unselected memory cells M0 to M9 connected between the selected memory cell M10 and the common source line CSL are not sufficiently turned on, ON-cell current flowing into the cell string STG is reduced by the unselected memory cells M0 to M9. Moreover, when the ground selection line GSL is supplied with a bias voltage by which the ground select transistor GST connected to the memory cell M0 and the common source line CSL is not sufficiently turned on, ON-on cell current flowing into the cell string STG is reduced through the ground select transistor GST. The reduced ON-cell current i0_{D} flows into the common source line CSL.

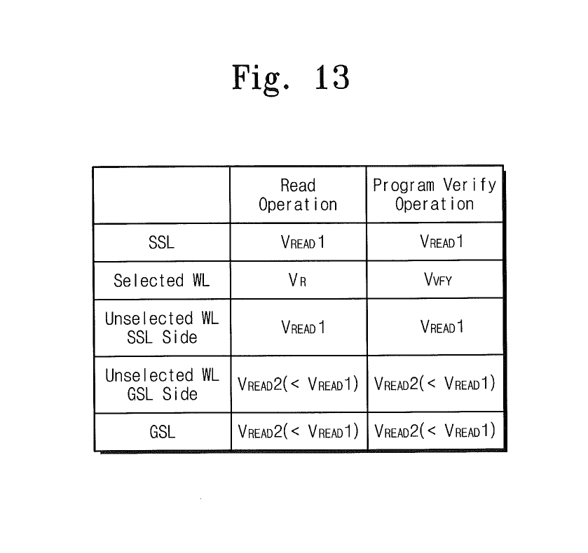

ON-cell current i0 to im flowing through a plurality of cell strings STG may be reduced according to bias voltages that are applied to unselected memory cells and the ground select transistor GST connected between the selected memory cell and the common source line CSL. The reduced ON-cell current i0 to im may flow into the common source line CSL. Accordingly, there is reduced the common source line voltage V_{CSL} increased in proportion to current flowing through the common source line CSL. Bias voltages applied to the select lines SSL and GSL and the word lines WL0 to WLn according to the forth embodiment of the inventive concept will be described in more detail with reference to FIG. 13.

FIG. 13 is a table illustrating bias voltage requirements in a cell string structure according to the fourth embodiment of the inventive concept.

Referring to FIGS. 12 and 13, there is shown a condition of bias voltages which are applied to the select lines SSL and GSL and the word lines WL0 and WLn during a read operation and a program verify operation.

The bias voltage condition for a read operation is as follows. A first non-select read voltage V_{READ}1 for sufficiently turning on the string select transistor SST is applied to the string select line SSL. A select read voltage V_{R} is applied to a selected word line to determine states (for example, an erase state and a program state) of selected memory cells. The first non-select read voltage V_{READ}1 is applied to unselected word lines (referred to as SSL-side unselected word lines) placed at an SSL side on the basis of the selected word line, in order to sufficiently turn on unselected memory cells connected with the SSL-side unselected word lines. The first non-select read voltage V_{READ}1 is higher than the select read voltage V_{R}.

A second non-select read voltage V_{READ}2 is applied to unselected word lines (referred to as GSL-side unselected word lines) placed at a GSL side on the basis of the selected word line, in order to insufficiently turn on unselected memory cells connected with the GSL-side unselected word lines. Here, the second non-select read voltage V_{READ}2 is higher than the ground voltage and is lower than the first non-select read voltage V_{READ}1. That is, the second non-select read voltage V_{READ}2 is used to reduce ON-cell current flowing into the common source line CSL through a cell string STG.

Furthermore, the second non-select read voltage V_{READ}2 is controlled so as not to affect reading of states (for example, an erase state and a program state) of selected memory cells. For example, the second non-select read voltage V_{READ}2 is controlled such that pre-charged charge on selected bit lines are discharged according to states of selected memory cells. Simultaneously, the second non-select read voltage V_{READ}2 is controlled such that ON-cell current flowing into the common source line CSL through a cell string STG is reduced. That is, the second non-select read voltage V_{READ}2 is controlled so as not to affect reading of states (for example, an erase state and a program state) of selected memory cells and so as to reduce ON-cell current flowing into the common source line CSL.

A bias condition for a program verify operation is as follows. A non-select read voltage V_{READ}1 is applied to the string select line SSL to sufficiently turn on a string select transistor SST. A program verify voltage V_{VFY} is applied to a selected word line to determine program states of selected memory cells. The non-select read voltage V_{READ}1 is applied to unselected word lines to sufficiently turn on unselected memory cells. The non-select read voltage V_{READ}1 for sufficiently turning on unselected memory cells is applied to the SSL-side unselected word lines. The first non-select read voltage V_{READ}1 is higher than the program verify voltage V_{VFY}.

A second non-select read voltage V_{READ}2 for not sufficiently turning on unselected memory cells is applied to the GSL-side unselected word lines. Here, the second non-select read voltage V_{READ}2 is higher than the ground voltage and is lower than the first non-select read voltage V_{READ}1. That is, the second non-select read voltage V_{READ}2 is used to reduce ON-cell current flowing in the common source line CSL through a cell string STG.

Furthermore, the second non-select read voltage V_{READ}2 is controlled not to affect reading of program states of selected memory cells. For example, the second non-select read voltage V_{READ}2 is controlled such that pre-charged charge on selected bit lines is discharged according to states of selected memory cells. Simultaneously, the second non-select read voltage V_{READ}2 is controlled such that ON-cell current flowing in the common source line CSL through a cell string STG is reduced. That is, the second non-select read voltage V_{READ}2 is controlled not to affect reading of program states of selected memory cells and so as to reduce an on cell current flowing in the common source line CSL.

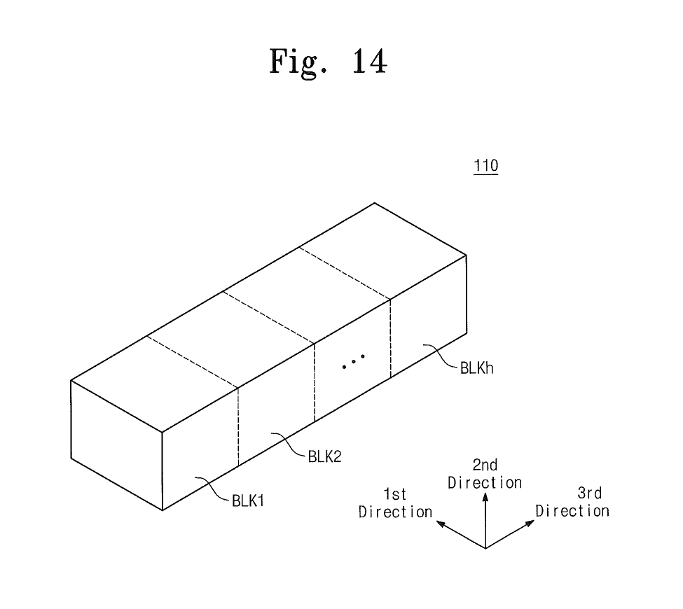

FIG. 14 is a block diagram illustrating a memory cell array according to an embodiment of the inventive concept.

Referring to FIG. 14, a memory cell array 110 includes a plurality of memory blocks BLK1 to BLKh, each of which has a three dimensional structure (or, vertical structure). For example, each of the memory blocks BLK1 to BLKh includes a plurality of structures extending along first to third directions. For example, each of the memory blocks BLK1 to BLKh includes a plurality of NAND strings extending along the second direction. For example, a plurality of NAND strings may be provided along the first and third directions.

Each NAND string is connected to a bit line, at least one string select line, at least one ground select line, word lines, at least one dummy word line, and a common source line. That is, each memory block is connected to a plurality of ground select lines, a plurality of word lines, a plurality of dummy word lines, and a plurality of common source lines. The memory blocks BLK1 to BLKh will be described in more detail with reference to FIG. 4.

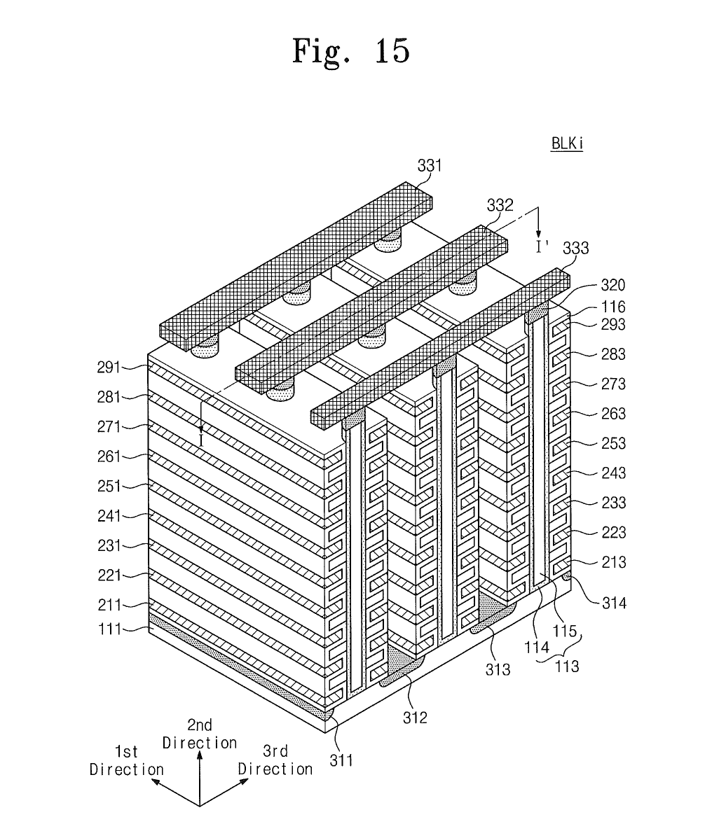

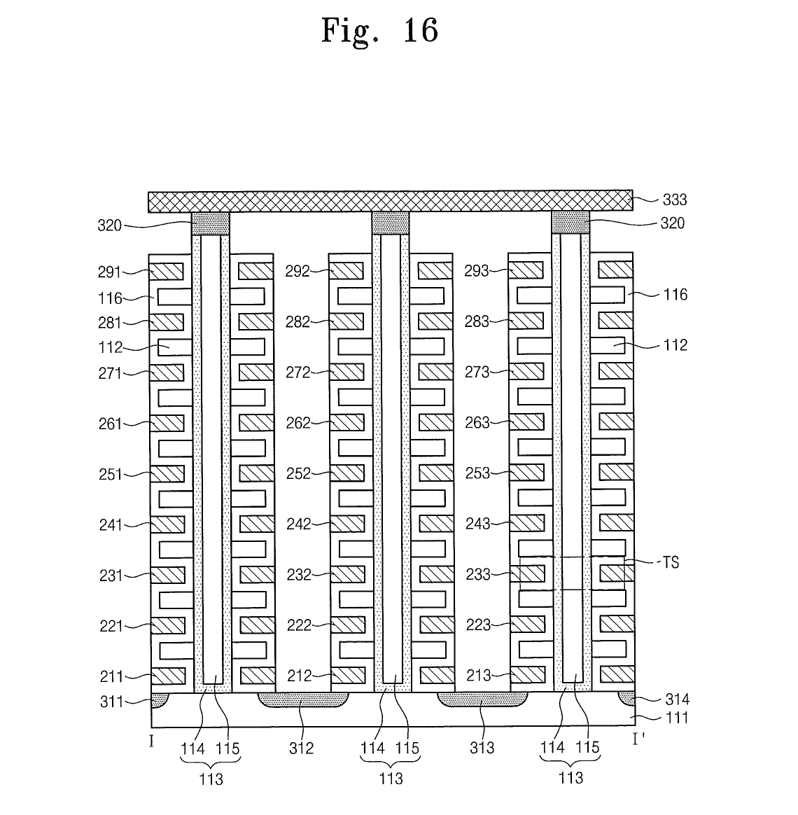

FIG. 15 is a perspective view illustrating one BLKi of the memory blocks BLK1 to BLKh. FIG. 16 is a cross-sectional view taken along the line I-I′ of the memory block BLKi. Referring to FIGS. 15 and 16, the memory block BLKi includes structures extending along the first to third directions.

First, a substrate 111 is provided. For example, the substrate 111 may include a silicon material doped with a first type impurity. For example, the substrate 111 may include a silicon material doped with a p-type impurity. For example, the substrate 111 may be a p-type well (for example, a pocket p well). For example, the substrate 111 may further include an n-type well surrounding a p-type well. Hereinafter, it is assumed that the substrate 111 is formed of p-type silicon. However, the substrate 111 is not limited to the p-type silicon.

A plurality of doping regions 311 to 314 extending along the first direction are provided in the substrate 111. For example, the plurality of doping regions 311 to 314 may have a second type different from the substrate 111. For example, the plurality of doping regions 311 to 314 may have an n-type. Hereinafter, it is assumed that the first to fourth doping regions 311 to 314 have the n-type, respectively. However, the first to fourth doping regions 311 to 314 are not limited to the n-type.

A plurality of insulation materials 112 are sequentially provided along the second direction in a substrate region between the first and second doping regions 311 and 312. For example, the plurality of insulation materials 112 and the substrate 111 may be spaced by a predetermined distance along the second direction. For example, the insulation materials 112 may include an insulation material such as a silicon oxide.

A plurality of pillars 113 are sequentially disposed along the first direction and penetrate the insulation materials 112 along the second direction in a substrate region between the first and second doping regions 311 and 312. For example, each of the pillars 113 penetrates the insulation materials 112 and then is connected to the substrate 111.

For example, each pillar 113 may be formed of a plurality of materials. For example, a surface layer 114 of each pillar 113 may include a silicon material doped with a first type. For example, hereinafter, it is assumed that the surface layer 114 of each pillar 113 includes p-type silicon. However, the surface layer 114 of each pillar 113 is not limited to the p-type silicon.

An inner layer 115 of each pillar 113 is formed of an insulation material. For example, the inner layer 115 of each pillar 113 may be filled with an insulation material such as silicon oxide.

An insulation layer 116 is provided along the exposed surfaces of the insulation materials 112, the pillars 113, and the substrate 111 in a region between the first and second doping regions 311 and 312. For example, a thickness of the insulation layer 116 may be less than the half of the distance between the insulation materials 112. That is, a region where a certain material is to be further disposed besides the insulation materials 112 and the insulation layer 116 may be provided between the insulation layer 116 on the bottom of the first insulation material in the insulation materials 112 and the insulation layer 116 on the top of the second insulation material below the bottom of the first insulation material.

Conductive materials 211 to 291 are provided on the exposed surface of the insulation layer 116 in a region between the first and second doping regions 311 and 312. For example, the conductive material 211 extending in the first direction between the insulation material 112 adjacent to the substrate 111 and the substrate 111. In more detail, the conductive material 211 extending in the first direction is provided between the insulation layer 116 on the bottom of the insulation material 112 adjacent to the substrate 111 and the substrate 111.

A conductive material extending along the first direction is provided between the insulation layer 116 on the top of a specific insulation material among the insulation materials 112 and the insulation layer 116 on the bottom of an insulation material above the specific insulation material. For example, a plurality of conductive materials 221 to 281 extending toward the first direction is provided between the insulation materials 112. Moreover, a conductive material 291 extending along the first direction is provided in a region above the insulation materials 112. For example, the conductive materials 211 to 291 extending in the first direction may be formed of a metal material. For example, the conductive materials 211 to 291 extending in the first direction may include poly silicon.

The same structure as the structure on the first and second doping regions 311 and 312 is provided in a region between the second and third doping regions. For example, a plurality of insulation materials 112 extending in the first direction, a plurality of pillars 113 disposed sequentially along the first direction and penetrating the plurality of insulation materials 112 along the third direction, an insulation layer 116 provided on the exposed surfaces of the plurality of insulation materials 112 and the plurality of pillars 133, and a plurality of conductive materials 212 to 292 extending along the first direction are provided in a region between the second and third doping regions 312 and 313.

The same structure as the structure on the first and second doping regions 311 and 312 is provided in a region between the third and fourth doping region 313 and 314. For example, a plurality of insulation materials 112 extending in the first direction, a plurality of pillars 113 disposed sequentially in the first direction and penetrating a plurality of insulation materials 112 along the third direction, an insulation layer 116 provided on the exposed surfaces of the plurality of insulation materials 112 and the plurality of pillars 113, and a plurality of conductive materials 213 to 293 extending along the first direction are provided in a region between the third and fourth doping regions 312 and 313.

Drains 320 are provided on the plurality of pillars 113, respectively. For example, the drains 320 may be formed of silicon materials doped with a second type. For example, the drains 320 may be formed of silicon materials doped with an n-type. Hereinafter, it is assumed that the drains 320 are foamed of n-type silicon. However, the drains 320 are not limited to the n-type silicon. For example, the width of each drain 320 may be greater than that of the pillar 113. For example, each drain 320 may be provided with a pad form on the top of the corresponding pillar 113.

Conductive materials 331 to 333 extending in the third direction are provided on the drains 320. The conductive materials 331 to 333 are sequentially disposed along the first direction. Each of the conductive materials 331 and 333 is connected to the drains 320 of a corresponding region. For example, the drains 320 and the conductive material 333 extending in the third direction may be connected through each contact plug. For example, the conductive materials 331 to 333 extending in the third direction may be formed of metal materials. For example, the conductive materials 331 to 333 extending in the third direction may include poly silicon.

Referring to FIGS. 15 and 16, in addition to an adjacent region of the insulation layer 116, an adjacent region of the plurality of conductive lines 211 to 291, 212 to 292, and 213 to 293 extending along the first direction, and each pillar 113 form a string. For example, each pillar 113, an adjacent region of the insulation layer 116, and an adjacent region of the conductive lines 211 to 291, 212 to 292, and 213 to 293 may constitute a NAND string NS. The NAND string NS includes a plurality of transistor structures TS. The transistor structure TS will be described in more detail with reference to FIG. 6.

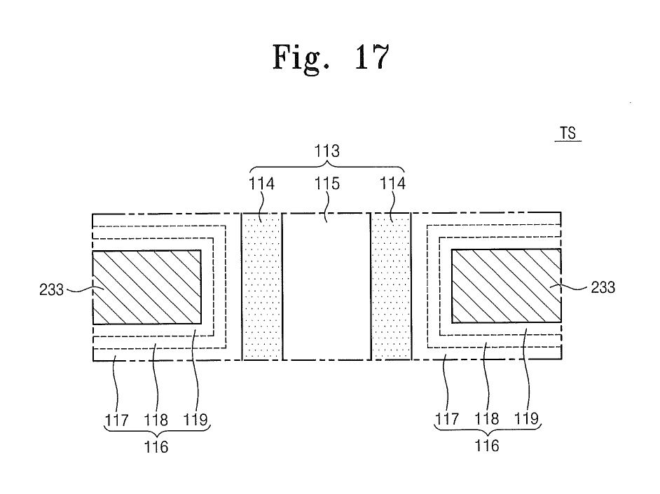

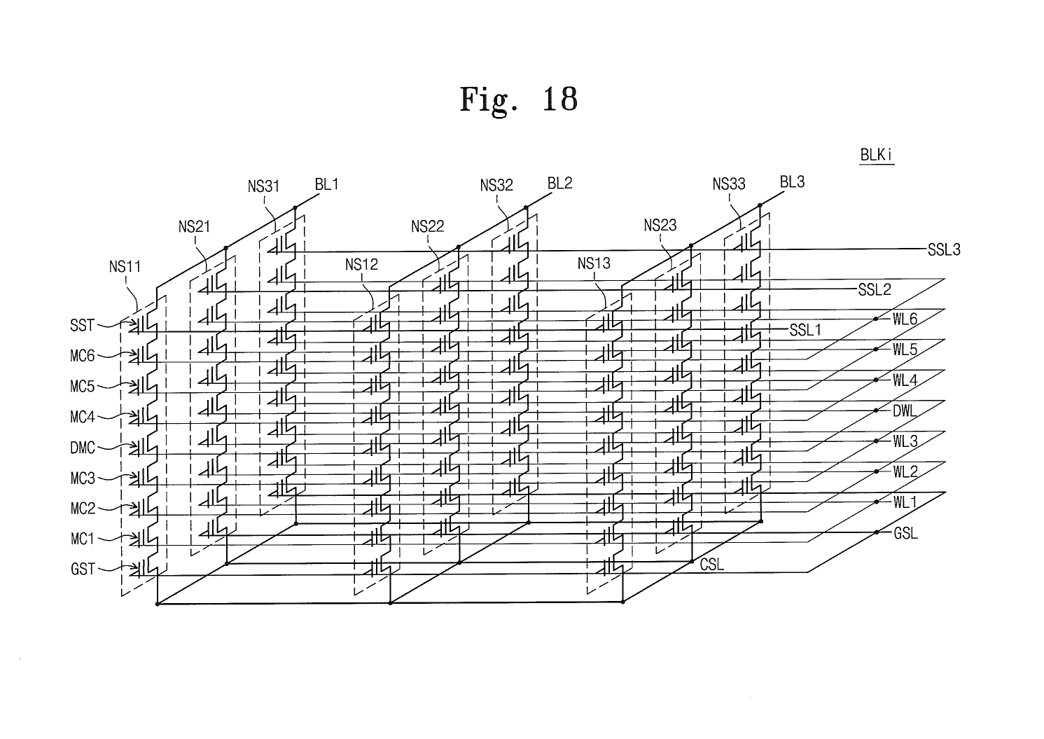

FIG. 17 is a cross-sectional view illustrating the transistor structure TS of FIG. 16.

Referring to FIGS. 15 to 17, the insulation layer 116 includes first to third sub insulation layers 117, 118, and 119. For example, the first sub insulation layer 117 adjacent to the pillar 113 may include a thermal oxide layer. The second sub insulation layer 118 may include a nitride layer or a metal oxide layer (for example, an aluminum oxide layer, a hafnium oxide layer and so forth). For example, the third sub insulation layer 119 adjacent to the conductive material 233 extending in the first direction may be formed of a single layer or a multi layer. The third sub insulation layer 119 may be formed of a high-k layer (for example, an aluminum oxide layer, a hafnium oxide layer and so forth) having a higher dielectric constant than the first and second sub insulation layers 117 and 118. For example, the first to third sub insulation layers 117 to 119 may constitute an oxide-nitride-oxide (ONO) layer.

The conductive material 223 may operate as a gate (or, a control gate). The third sub insulation layer 119 adjacent to the conductive material 233 may operate as a blocking insulation layer. The second sub insulation layer 118 may operate as a charge storing layer. For example, the second sub insulation layer 118 may operate a charge trapping layer. The first sub insulation layer 117 adjacent to the pillar 113 may operate as a tunneling insulation layer. The p-type silicon 114 of the pillar 113 may operate as a body. That is, the gate (or, a control gate 233), the blocking insulation layer 119, the charge storing layer 118, the tunneling insulation layer 117, and the body 114 may constitute a transistor (or, a memory cell transistor structure). Hereinafter, the p-type silicon 114 of the pillar 113 is called a body of the second direction.

The memory block BLKi includes a plurality of pillars 113. That is, the memory block BLKi includes a plurality of NAND strings NS. In more detail, the memory block BLKi includes a plurality of NAND strings NS extending in the second direction (or, perpendicular to the substrate).

Each NAND string NS includes a plurality of transistor structures TS disposed along the second direction. At least one transistor structure TS of each NAND string NS operates as a string select transistor SST. At least one transistor structure TS of each NAND string NS may operate as a ground select transistor GST.

Gates (or, control gates) correspond to the conductive materials 211 to 291, 212 to 292, and 213 to 293 extending in the first direction. That is, gates (or, control gates) form word lines extending in the first direction and at least two select lines (for example, at least one string select line SSL and at least one ground select line GSL).

The conductive materials 331 to 333 extending in the third direction are connected to one end of the NAND strings NS. For example, the conductive materials 331 to 333 extending in the third direction operate as bit lines BL. That is, a plurality of NAND strings NS is connected to one bit line BL in one memory block BLKi.

The second type doping regions 311 to 314 extending in the first direction are provided at the other end of the NAND string. The second type doping regions 311 to 314 extending in the first direction operate as common source lines CSL.

In summary, the memory block BLKi includes a plurality of NAND strings extending in a vertical direction (i.e., the second direction) with respect to the substrate 111 and may operate as a NAND flash memory block (e.g., a charge trapping type) where a plurality of NAND strings NS are connected to one bit line BL.

In FIGS. 15 to 17, it is described that the conductive lines 211 to 291, 212 to 292, and 213 to 293 are provided as nine layers. However, the conductive lines 211 to 291, 212 to 292, and 213 to 293 extending in the first direction are not limited thereto. For example, conductive lines extending in the first direction may be provided as 8 layers, 16 layers, or a plurality of layers. That is, transistors may be 8, 16, or in plurality.

Referring to FIGS. 15 through 17, it is described that three NAND strings NS are connected to one bit line BL. However, this inventive concept is not limited thereto. For example, four or more NAND strings NS may be connected to one bit line BL in the memory block BLKi. At this point, according to the number of NAND strings NS connected to the bit line BL, the number of conductive materials 211 to 291, 212 to 292, and 213 to 293 extending in the first direction and the number of the common source lines 311 to 315 will be adjusted.

Referring to FIGS. 15 to 17, it is described that three NAND strings NS are connected to one conductive material extending in the first direction. However, this inventive concept is not limited thereto. For example, the n number of NAND strings NS may be connected to one conducive material extending in the first direction. At this point, according to the number of NAND strings NS connected to one conductive material extending in the first direction, the number of bit lines 331 to 333 will be adjusted.

FIG. 18 is a circuit diagram illustrating an equivalent circuit of the memory block BLKi described with reference to FIGS. 15 through 17.

Referring to FIGS. 15 through 18, NAND strings NS11 to NS31 are provided between the first bit line BL1 and the common source line CSL. The first bit line BL1 corresponds to the conductive material 331 extending in the third direction. NAND strings NS12, NS22, and NS32 are provided between the second bit line BL2 and the common source line CSL. The second bit line BL2 corresponds to the conductive material 332 extending in the third direction. The NAND strings NS13, NS23, and NS33 are provided between the third bit line BL3 and the common source line CSL. The third bit line BL3 corresponds to the conductive material 333 extending in the third direction.

The string select transistor SST of each NAND string NS is connected to a corresponding bit line BL. The ground select transistor GST of each NAND string NS is connected to the common source line CSL. Memory cells MC are provided between the string select transistor SST and the ground select transistor GST of each NAND string.

Hereinafter, the NAND string is defined by row and column units. NAND strings NS commonly connected to one bit line form one column. For example, the NAND strings NS11 to NS31 connected to a first bit line BL1 correspond to a first column. The NAND strings NS12 to NS32 connected to the second bit line BL2 corresponds to a second column. The NAND strings NS13 to NS33 connected to a third bit line BL3 correspond to a third column.

NAND strings NS connected to one string select line SSL form one row. For example, the NAND strings NS11 to NS13 connected to the first string select line SSL1 form a first row. The NAND strings NS21 to NS23 connected to a second string select line SSL2 form a second row. The NAND strings NS31 to NS33 connected to the third string select line SSL3 form a third row.

The height is defined in each NAND string NS. For example, in each NAND string NS, the height of a memory cell MC1 adjacent to the ground select transistor GST is 1. The height of a memory cell increases as being closer to the string select transistor SST in each NAND sting NS. In each NAND string NS, the height of a memory cell MC6 adjacent to the string select transistor SST is 7.

The string select transistors SST of the NAND strings NS in the same row share the string select line SSL. The string select transistors SST of the NAND stings NS in the different rows are connected to the different string select lines SSL1, SSL2, and SSL3, respectively.

Memory cells, having the same height, of the NAND strings NS in the same row share a word line WL. Word lines are commonly connected which are connected with memory cells of the NAND strings NS placed at the same height and belonging to different rows. Dummy memory cells DMC, having the same height, of the NAND strings NS in the same row share a dummy word line DWL. The dummy word lines DWL are commonly connected which are connected with dummy memory cells DMC of the NAND strings NS placed at the same height and belonging to different rows.

For example, the word lines WL or the dummy word lines DWL may be commonly connected in a layer where the conductive materials 211 to 291, 212 to 292, and 213 to 293 extend in the first direction. For example, the conductive materials 211 to 291, 212 to 292, and 213 to 293 extending in the first direction may be connected to the top layer through contacts. The conductive materials 211 to 291, 212 to 292, and 213 to 293 extending in the first direction may be commonly connected at the top layer.

The ground select transistors GST of the NAND strings NS in the same row share the ground select line GSL. The ground select transistors GST of the NAND strings NS in different rows share the ground select line GSL. That is, the NAND strings NS11 to NS13, NS21 to NS23, and NS31 to NS33 may be commonly connected to the ground select line GSL.

The common source line CSL is commonly connected to the NAND strings NS. For example, the first to fourth doping regions 311 to 314 may be connected at an active region in the substrate 111. For example, the first to fourth doping regions 311 to 314 may be connected to the top layer through contacts. The first to fourth doping regions 311 to 314 may be commonly connected at the top layer.

As shown in FIG. 18, the word lines WL of the same depth are commonly connected. Accordingly, when a specific word line WL is selected, all NAND strings NS connected to the specific word line WL will be selected. The NAND strings NS in different rows are connected to different string select lines SSL. Accordingly, by selecting the string select lines SSL1 to SSL3, the NAND strings in an unselected row among NAND strings NS connected to the same word line WL may be separated from the bit lines BL1 to BL3. That is, by selecting the string select lines SSL1 to SSL3, a row of the NAND strings may be selected. Then, by selecting the bit lines BL1 to BL3, the NAND strings NS of the selected row may be selected by a row unit.

In each NAND string NS, a dummy memory cell DMC is provided. First to third memory cells MC1 to MC3 are provided between the dummy memory cell DMC and the ground select line GST. Fourth to sixth memory cells MC4 to MC6 are provided between the dummy memory cell DMC and the string select line SSL. Hereinafter, it is assumed that the memory cells MC of each NAND string NS are divided into memory cell groups by the dummy memory cell DMC. Among the divided memory cell groups, memory cells (for example, MC1 to MC3) adjacent to the ground select transistor GST are called a bottom memory cell group. Then, among the divided memory cell groups, memory cells (for example, MC4 to MC6) adjacent to the string select transistor SST are called a top memory cell group.

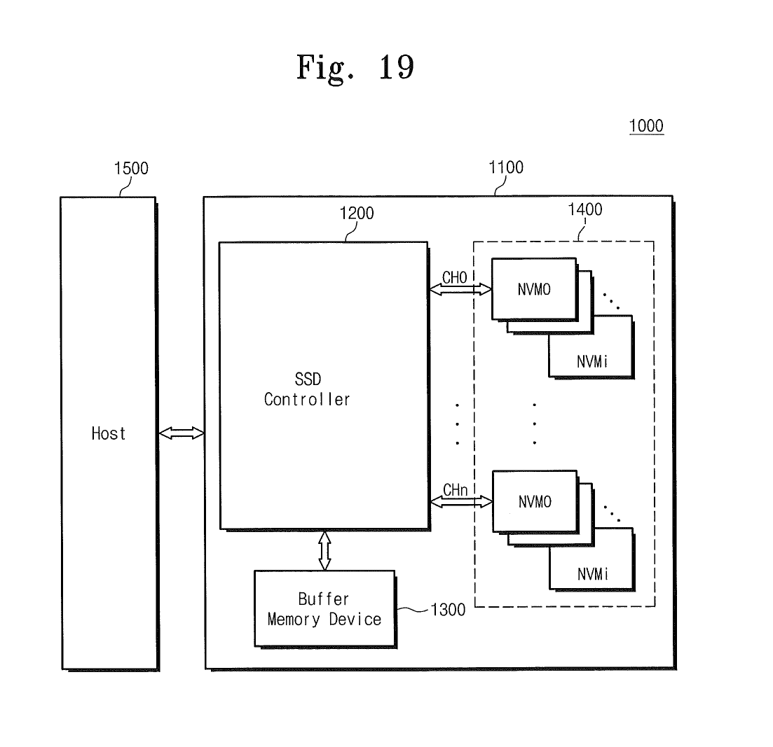

FIG. 19 is a block diagram illustrating a user device including a nonvolatile memory device according to an embodiment of the inventive concept.

Referring to FIG. 19, a data storage device 1000 may be a Solid State Drive (SSD). The SSD 1100 includes a SSD controller 1200, a buffer memory device 1300, and a storage medium 1400. The SSD 1100 may further include a temporary power circuit with super capacitors. This temporary power circuit supplies power to allow the SSD 1100 to be terminated normally upon sudden power-off.

The SSD 1100 operates in response to an access request of the host 1500. That is, in response to the request from the host 1500, the SSD controller 1200 is configured to access the storage medium 1400. For example, the SSD controller 1200 is configured to control read, write, and erase operations of the storage medium 1400. The buffer memory device 1300 temporarily stores data to be stored in the storage medium 1400. In addition, data read from the storage medium 1400 are temporarily stored in the buffer memory device 1300. The data stored in the buffer memory device 1300 may be transmitted to the storage medium 1400 or the host 1500 according to a control of the SSD controller 1200.

The SSD controller 1200 is connected to the storage medium 1400 through a plurality of channels CHO to CHn, each of which is connected with a plurality of nonvolatile memory devices NVM0 to NVMi. The plurality of nonvolatile memory devices NVM0 to NVMi may share a channel. The storage medium 1400 may include a NAND flash memory device. However, the storage medium 1400 is not limited thereto. For example, the storage medium 1400 may include one of nonvolatile memory devices such as a NOR flash memory device, a phase-change RAM (PRAM), an ferroelectric RAM (FRAM), and a magnetic RAM (MRAM).

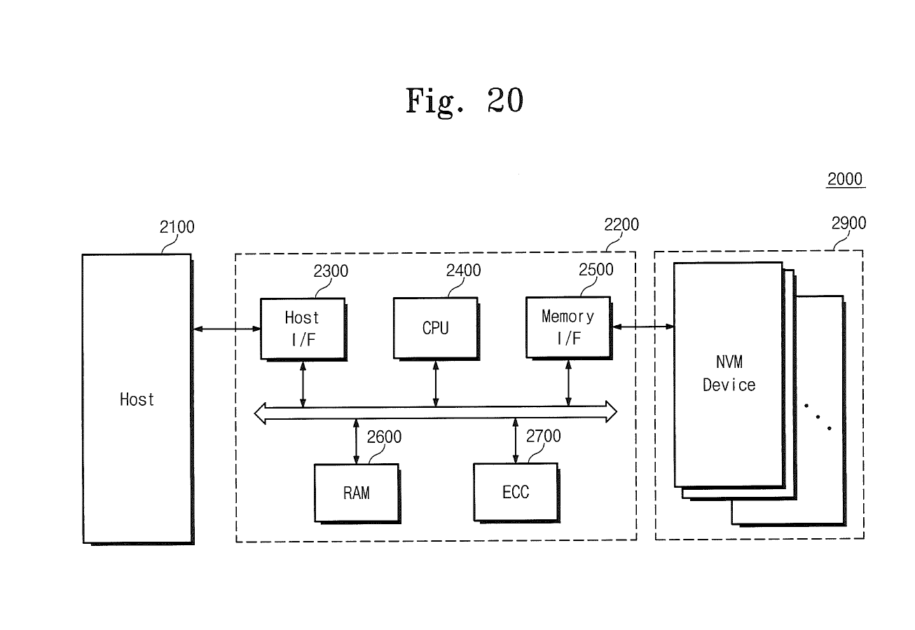

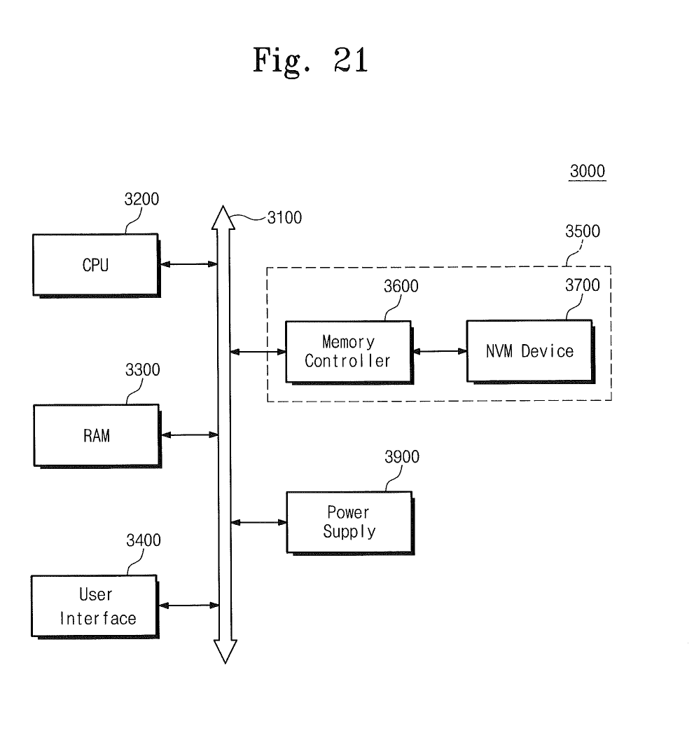

FIG. 20 is a block diagram illustrating another user device including a nonvolatile memory device according to an embodiment of the inventive concept.

Referring to FIG. 20, a memory system 2000 includes a memory controller 2200 and a nonvolatile memory device. The memory system 2000 may include a plurality of nonvolatile memory devices. The memory system 2000 according to the embodiment of the inventive concept includes a plurality of nonvolatile memory devices 2900.

A memory controller 2200 is connected to a host 2100 and the nonvolatile memory devices 2900. In response to a request from the host 2100, the memory controller 2200 is configured to access the nonvolatile memory devices 2900. For example, the memory controller 2200 is configured to control read, write, and erase operations of the nonvolatile memory devices 2900. The memory controller 2200 is configured to provide an interface between the nonvolatile memory devices 2900 and the host 2100. The memory controller 2200 is configured to drive firmware for controlling the nonvolatile memory devices 2900.

The memory controller 2200 may include typical components such as a random access memory (RAM), a central processing unit (CPU), a host interface, an error correcting code (ECC), and a memory interface. The RAM 2600 may serve as a wording memory of the CPU 2400. The CPU 2400 controls general operations of the memory controller 2200.

The host interface 2300 may include a protocol for performing data exchange between the host 2100 and the memory controller 2200. For example, the memory controller 2200 may be configured to communicate with an external device (e.g., the host) through one of various interface protocols such as USB (Universal Serial Bus), MMC (Multimedia Card), PCI (Peripheral Component Interface), PCI-E (PCI-Express), ATA (Advanced Technology Attachment), Serial-ATA, Parallel-ATA, SCSI (Small Computer Small Interface), ESDI (Enhanced Small Disk Interface), and IDE (Integrated Drive Electronics).

The ECC 2700 may be configured to detect errors of data read from the nonvolatile memory devices 2900 and then, correct them. The ECC 2700 may be provided as a component of the memory controller 2200. As another example, the ECC 2700 may be provided as a component of the nonvolatile memory devices 2900. The memory interface 2500 may allow the nonvolatile memory devices 2900 to interface with the memory controller 2200.

It is apparent that components of the memory controller 2220 are not limited to the above mentioned components. For example, the memory controller 2200 may further include code data necessary for initial booting and a read only memory (ROM) for storing data used to interface with the host 2100.

The memory controller 2200 and the nonvolatile memory devices 2900 may be integrated into one semiconductor device and then may constitute a memory card. For example, the controller 2200 and the nonvolatile memory device 2900 may be integrated into one semiconductor device to constitute a personal computer memory card international association (PCMCIA) card, a compact flash (CF) card, a smart media card, a memory stick, a multimedia card (e.g., MMC, RS-MMC, and MMCmicro), a secure digital (SD) card (e.g., SD, mini-SD, micro-SD, and SDHC), or a universal flash storage (UFS).

As another example, the memory controller 2200 and the nonvolatile memory devices 2900 may be applied to SSDs, computers, portable computers, ultra mobile personal computers (UMPCs), work stations, net-books, personal digital assistants (PDAs), web tablets, wireless phones, mobile phones, digital cameras, digital audio recorders, digital audio players, digital video recorders, digital video players, devices for transmitting/receiving information in wireless environments, one of various electronic devices constituting a home network, one of various electronic devices constituting a computer network, one of various electronic devices constituting a telematics network, an RFID device, or one of various components constituting a computing system, a radio frequency identification (RFID) device, or an embedded system.

As anther embodiment, the nonvolatile memory device 2900 or the memory controller 2200 may be mounted using various kinds of packages. Examples of the packages of the nonvolatile memory device 2900 or the memory controller 2200 include Package on Package (PoP), Ball Grid Arrays (BGA), Chip Scale Packages (CSP), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), and Wafer-level Processed Stack Package (WSP).

FIG. 21 is a block diagram illustrating another user device including a nonvolatile memory device according to an embodiment of the inventive concept.

Referring to FIG. 21, a user device 3000 includes a system bus 3100, a CPU 3200, a RAM 3300, a user interface 3400, a data storage device 3500, and a power supply device 3900.

The data storage device 3500 is electrically connected to the user device 3000 through the system bus 3000. The data storage device 3500 includes a memory controller 3600 and a nonvolatile memory device 3700. The data storage device 3500 may include a plurality of nonvolatile memory devices. The nonvolatile memory device 3700 temporarily stores data, which are provided through the user interface 3400 or processed by the CPU 3200, through the memory controller 3600. The data stored in the nonvolatile memory device 3700 may be provided to the CPU 3200 or the user interface 3400 through the memory controller 3600.

The RAM 3300 may serve as a working memory of the CPU 3200. The power supply device 3900 supplies an operating power to the user device 3000. For example, in order to improve portability of the user device 3000, a power supply device such as a battery is provided. Although not illustrated in the drawings, it is apparent that a user device according to the inventive concept may further include an application chipset, a camera image processor.

With the inventive concept, a threshold voltage distribution of memory cells caused by a noise voltage of a common source line can be prevented from being expanded in width.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A nonvolatile memory device comprising:
a memory cell;
a transistor disposed between a common source line and the memory cell; and
a control logic for controlling a bias voltage of the transistor to reduce the amount of current flowing into the common source line during a read operation.

2. The nonvolatile memory device of claim 1, wherein the transistor operates in a triode state according to the bias voltage.

3. The nonvolatile memory device of claim 1, wherein the bias voltage applied to the transistor is higher than a bias voltage applied to the memory cell.

4. The nonvolatile memory device of claim 1, further comprising a plurality of memory cells disposed between a bit line and the common source line and connected in series to the memory cell.

5. A nonvolatile memory device comprising:
a plurality of memory cells connected in series;
a transistor between a common source line and the plurality of memory cells; and
a control logic for controlling bias voltages applied to the plurality of memory cells and the transistor,
wherein the control logic controls a non-select read voltage applied to an unselected memory cell among the plurality of memory cells and a bias voltage of the transistor to reduce the amount of current flowing into the common source line during a read operation.

6. The nonvolatile memory device of claim 5, wherein the bias voltage of the transistor is higher than a ground voltage and is lower than the non-select read voltage.

7. The nonvolatile memory device of claim 5, wherein the bias voltage of the transistor is higher than a bias voltage applied to a selected memory cell among the plurality of memory cells.

8. The nonvolatile memory device of claim 5, wherein the control logic controls a select read voltage applied to a selected memory cell among the plurality of memory cells.

9. The nonvolatile memory device of claim 8, wherein the select read voltage is a read voltage for determining one of an erase state and a program state of the selected memory cell.

10. The nonvolatile memory device of claim 8, wherein the select read voltage is a program verify voltage for determining a program state of the selected memory cell.

11. The nonvolatile memory device of claim 8, wherein the non-select read voltage is higher than the select read voltage.

12. The nonvolatile memory device of claim 5, wherein the transistor has the same structure as the memory cell.

13. The nonvolatile memory device of claim 12, wherein the transistor is programmed before a read operation or a program operation is performed.

14. The nonvolatile memory device of claim 13, wherein a threshold voltage of the transistor is higher than a select read voltage applied to a selected memory cell among the plurality of memory cells and is lower than the non-select read voltage.

15. The nonvolatile memory device of claim 13, wherein the non-select read voltage is the same as a bias voltage of the transistor.

16. The nonvolatile memory device of claim 5, wherein:
a first non-select read voltage is applied to a first unselected memory cell connected to between a selected memory cell among the plurality of memory cells and the common source line;
a second non-select read voltage is applied to a second unselected memory cell connected to between the selected memory cell and the bit line; and
the first non-select read voltage is higher than a ground voltage and is lower than the second non-select read voltage.

17. The nonvolatile memory device of claim 16, wherein the first non-select read voltage is higher than a bias voltage applied to the selected memory cell.

18. A method of reading a nonvolatile memory device including a memory cell and a transistor between a common source line and the memory cell, the method comprising:
applying a read voltage to the memory cell; and
controlling a bias voltage of the transistor to reduce the amount of current flowing into the common source line.

19. The method of claim 18, wherein the bias voltage of the transistor is higher than the read voltage.

20. The method of claim 18, wherein the transistor comprises a memory cell transistor having the same structure as the memory cell and the method further includes programming the memory cell transistor before the read voltage is applied.
